(19) United States
(12) Patent Application Publication
(10) Pub. No.: US 2025/0308994 A1
(43) Pub. Date: Oct. 2, 2025

(54) SMALL MOLECULES FOR SELECTIVE DEPOSITION

(71) Applicant: Intel Corporation, Santa Clara, CA (US)

(72) Inventors: Scott SEMPRONI, Fair Lawn, NJ (US); Charles MOKHTARZADEH, Portland, OR (US)

(21) Appl. No.: 18/622,271

(22) Filed: Mar. 29, 2024

(51) Int. Cl. H01L 21/768; H01L 23/498; H01L 23/532

(52) U.S. Cl. CPC H01L 21/76879; H01L 21/76831; H01L 23/49816; H01L 23/53238; H01L 23/53266; H01L 23/53276; H01L 23/5329

(57) ABSTRACT

Semiconductor devices having a conductive layer comprising carbon and nitrogen are provided. Semiconductor devices can include regions having dielectric on dielectric structures. Semiconductor devices can also include a conductive layer comprising carbon and nitrogen that is between two conductive regions. Methods of manufacturing semiconductor devices using reagents comprising isocyanate molecules are provided.

### FIELD

Descriptions are generally related to semiconductor device manufacture, and more particular descriptions are related to selective deposition processes.

### BACKGROUND

Semiconductor devices are central to intelligent devices and systems, such as personal computers, laptops, tablets, phones, servers, and other consumer and industrial products and systems. Manufacturing semiconductor devices presents a number of challenges and these challenges are amplified as semiconductor chips become smaller and performance demands increase. Challenges include, for example, unwanted material interactions, precision and scaling requirements, power delivery requirements, limited failure tolerance, and material and manufacturing costs.

As integrated circuit feature sizes decrease, the number of rounds of lithography and etch processes increase in order to accomplish required tighter pitches. At tighter pitches, overlay mismatches between circuit elements can increasingly reduce device reliability and yield. Lithography in general is used in the semiconductor manufacturing industry to create features on a semiconductor chip by creating a pattern in a layer of photosensitive material and, for example, depositing a material on the surface and into the revealed areas or etching the surface in revealed areas. A photosensitive material is, for example, a photoresist. To pattern the photoresist, a lithographic photomask is used as a template to create a light pattern which exposes only a portion of the photoresist. Depending on the type of photoresist selected, a semiconductor process such as exposing the patterned surface to a solvent, removes either the exposed or the unexposed sections of the photoresist from the surface of the chip being manufactured. As layers of materials are built up to create devices and circuits, overlay mismatches can occur with features created by subsequent lithographic processes.

### BRIEF DESCRIPTION OF THE DRAWINGS

The figures are provided to aid in understanding the disclosure. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIG. 1 illustrates a section of a semiconductor device that includes a dielectric-on-dielectric region and a residual process region.

FIG. 2 provides an additional structure in a section of a semiconductor device that includes a residual process region.

FIG. 3 shows a packaged semiconductor device comprising a residual process region.

FIGS. 4A-4B illustrate an additional method of manufacturing trenches and/or vias in a semiconductor device.

FIGS. 5A-5B show a method of manufacturing trenches and/or vias in a semiconductor device.

FIG. 6 provides isocyanide molecules that can be used to manufacture manufacturing trenches and/or vias in a semiconductor device.

FIG. 7 describes a method for manufacturing trenches and/or vias in a semiconductor device that employs reagents comprising isocyanide molecules.

FIG. 8 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, or hardwired circuitry). Other components can be semiconductor processing equipment that is able to perform physical operations such as, for example, lithography, material deposition (for example, chemical vapor deposition (CVD), atomic layer deposition (ALD), and/or sputtering), chemical mechanical polishing, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, silicon dioxide (SiO₂), silicon nitride (SiN), silicon carbide (SiC), and/or silicon carbonitride (SiCN). Low-K dielectrics have a lower dielectric constant than SiO₂. Low-K dielectrics include for example, fluorine-doped SiO₂, carbon-doped SiO₂, porous SiO₂, porous carbon-doped SiO₂, combinations for the foregoing, and also these materials with gas-filled gaps. Dielectric layers that include conductive features can be interlayer dielectric (ILD) features.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard or other printed circuit board for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

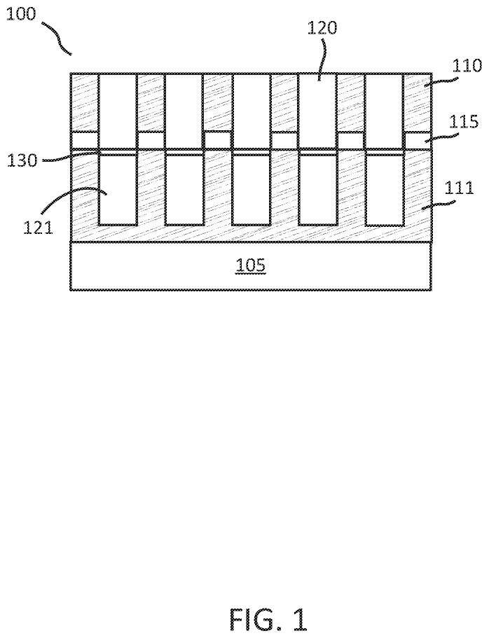

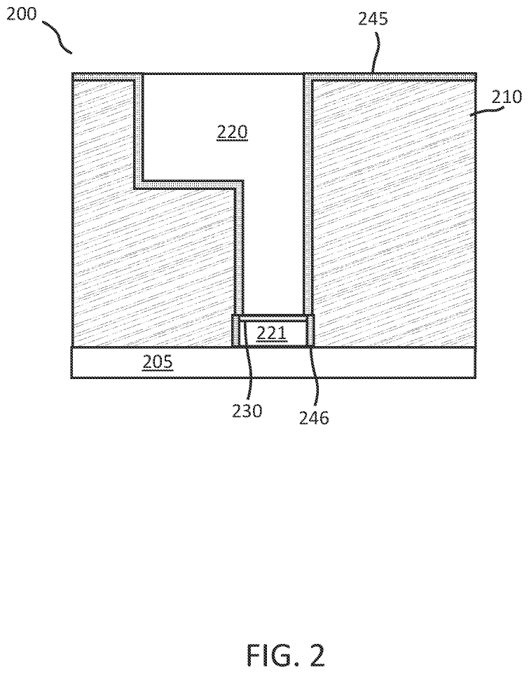

FIG. 1 provides a section of a semiconductor device comprising conductive traces and/or vias that also includes a dielectric-on-dielectric region. In FIG. 1, device section 100 includes substrate 105, first dielectric regions 110 and 111, second dielectric regions 115, and conductive regions 120 and 121. Other regions and/or layers are also possible, such as, for example, layers between the conductive regions 120 and 121 and the dielectric regions 110, 111, and 115. Layers between the conductive regions 120 and 121 and the dielectric regions 110, 111, and 115 can be one or more layers having compositions such as, for example, those described with respect to FIG. 2 and barrier layers 245 and 246. Substrate 105 can be a portion of a semiconductor device and can include layers containing semiconductor devices, such as transistors and/or memory cells. First dielectric regions 110 and 111 can be comprised of a dielectric material such as, for example, SiO₂, SiCN, SiCO, or a low-K dielectric material. Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. First dielectric regions 110 and 111 can be ILDs. Second dielectric regions 115 can comprise a dielectric material that can act as an etch stop during semiconductor device manufacture, such as, for example, SiO₂, silicon nitride (SiN), silicon carbide (SiC), silicon carbonitride (SiCN), SiCO, aluminum oxide (Al₂O₃), titanium dioxide (TiO₂), tantalum nitride (TaN), aluminum nitride (AlN), zirconium oxide (ZrO₂), hafnium oxide (HfO₂), tungsten carbonitride (WCN), tungsten carbide (WCₓ), boron nitride (BN), boron carbonitride (BCN), and/or carbon hardmask (CHM). Second dielectric regions 115 can comprise two different dielectric materials, where an etch stop material is, for example, a layer on a low-K dielectric material. Alternatively, the second dielectric regions 115 can be comprised solely of an etch stop material.

Conductive regions 120 and 121 can be comprised of a metal, for example, copper, tungsten, molybdenum, ruthenium, cobalt, or an alloy thereof. Conductive regions 120 and 121 can comprise, for example, copper with a layer of tungsten, cobalt, molybdenum, and/or ruthenium. Alloys of copper and manganese can also be used. Conductive regions 120 and 121 can be conductive structures that are traces or vias. Conductive regions 121 also include residual process region 130. Residual process region 130 is a conductive region that is comprised of a conductive material, such as for example, copper tungsten, molybdenum, and/or ruthenium, that also includes an amount of carbon and/or nitrogen that remains from a process used during the manufacture of the semiconductor device. Residual process region 130 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in a conductive material, such as a metal. Additionally, residual process region 130 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in copper. Additionally, the residual process region 130 can comprise 1 to 10% by weight of carbon and nitrogen and one or more additional parts of oxygen, sulfur, boron, phosphorous, and/or silicon. The composition of the residual process region 130 can depend, at least in part, on the organic isocyanide molecules (R—NC) selected.

FIG. 2 illustrates a portion of a semiconductor device comprising conductive traces and/or vias and a conductive residual process region. In FIG. 2, device section 200 includes substrate 205, dielectric region 210, conductive regions 220 and 221, and barrier layers 245 and 246. Substrate 205 can be a portion of a semiconductor device and can include layers containing semiconductor devices, such as transistors and memory cells. Dielectric region 210 can be comprised of a dielectric material such as, for example, SiO₂, SiCN, SiCO, or a low-K dielectric material. Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric region 210 can be an interlayer dielectric region. Barrier layers 245 and 246 are between dielectric region 210 and the conductive region 220 and 221, respectively. Barrier layers 245 and 246 can be comprised of, for example, one or more layers of tantalum, tantalum nitride, cobalt, ruthenium, indium oxide, tungsten nitride, and/or titanium nitride. Alloys of the foregoing are also possible, such as, for example, TaRuCo or TaNRuCo. Other materials are possible. In general, barrier layers are layers of material that are capable of preventing the migration of material from a conductive region into a dielectric region.

Conductive regions 220 and 221 can be comprised of a metal, for example, copper, tungsten, molybdenum, ruthenium, cobalt, or an alloy thereof. Conductive regions 220 and 221 can comprise, for example, copper with a layer of tungsten, cobalt, molybdenum, ruthenium, or an alloy thereof. Alloys of copper and manganese can also be used. Conductive regions 220 and 221 can be conductive structures that are traces or vias. Conductive regions 221 also include conductive residual process region 230. Conductive residual process region 230 is comprised of a conductive material, such as for example, copper, tungsten, molybdenum, and/or ruthenium, that also includes an amount of carbon and/or nitrogen that remains from a process used during the manufacture of the semiconductor device. Conductive residual process region 230 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in a conductive material, such as a metal. Additionally, conductive residual process region 230 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in copper. Additionally, the residual process region 230 can comprise 1 to 10% by weight of carbon and nitrogen and one or more additional parts of oxygen, sulfur, boron, phosphorous, and/or silicon. The composition of the residual process region 230 can depend, at least in part, on the organic isocyanide molecules (R—NC) selected.

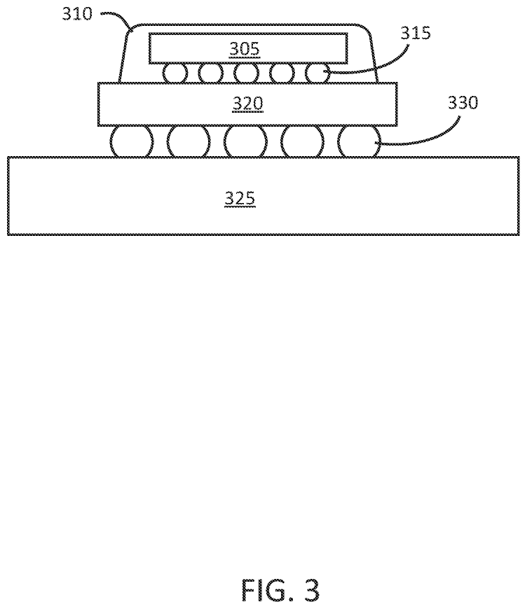

FIG. 3 provides an example of a packaged semiconductor device. The semiconductor device 305 can be a device having a residual process region, such as the devices of FIGS. 1 and/or 2. In FIG. 3, the semiconductor device 305 is enclosed with an encapsulant 310 and coupled to a package substrate 320 through first level interconnects 315. First level interconnects 315 can be comprised of conductive regions such as, for example, solder, pins, bumps, and/or pads. Package substrate 320 is coupled to a circuit board 325 through second interconnects 330. The circuit board 325 can be, for example, a motherboard, a printed circuit board, a logic board. Circuit board 325 can provide power to and interconnections between semiconductor devices (305). Second interconnects 330 can be comprised of conductive regions such as, for example, solder, pins, bumps, pads and/or a connector.

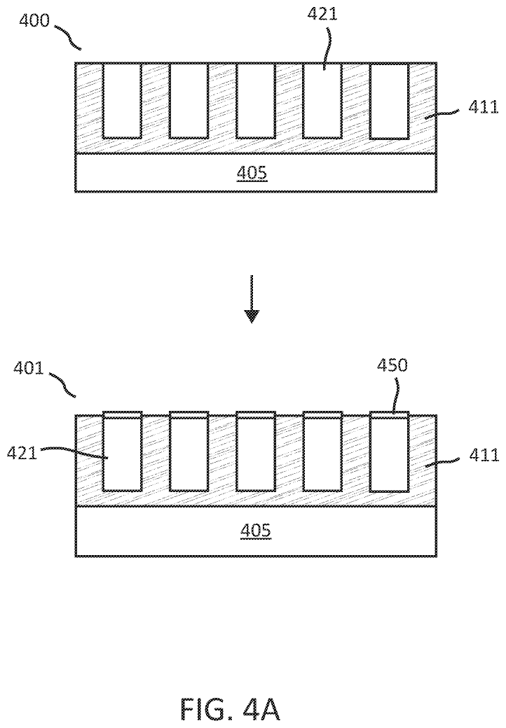

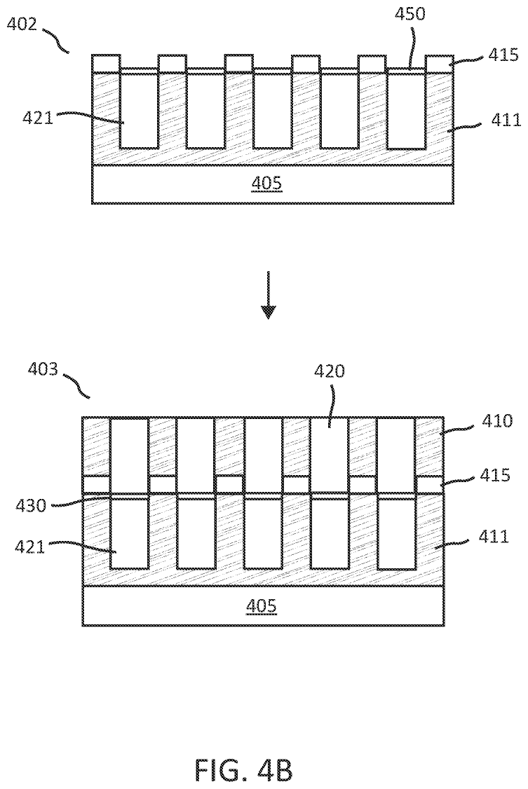

FIGS. 4A-4B illustrate a method of manufacturing a semiconductor device. The semiconductor device can be, for example, the semiconductor device of FIG. 1. Partially manufactured semiconductor device 400 includes a substrate 405, first dielectric region 411, and first conductive regions 421. Other regions and/or layers are also possible, such as, for example, layers between the conductive region 421 and the dielectric region 411. Layers between the conductive regions 421 and the dielectric region 411 can be one or more layers having compositions such as, for example, those described with respect to FIG. 2 and barrier layers 245 and 246. Substrate 405 can be a portion of a semiconductor device and can include layers containing semiconductor devices, such as transistors or memory cells. First dielectric region 411 can be comprised of a dielectric material such as, for example, SiO₂, SiCN, SiCO, or a low-K dielectric material. Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. First dielectric region 411 can be an ILD region.

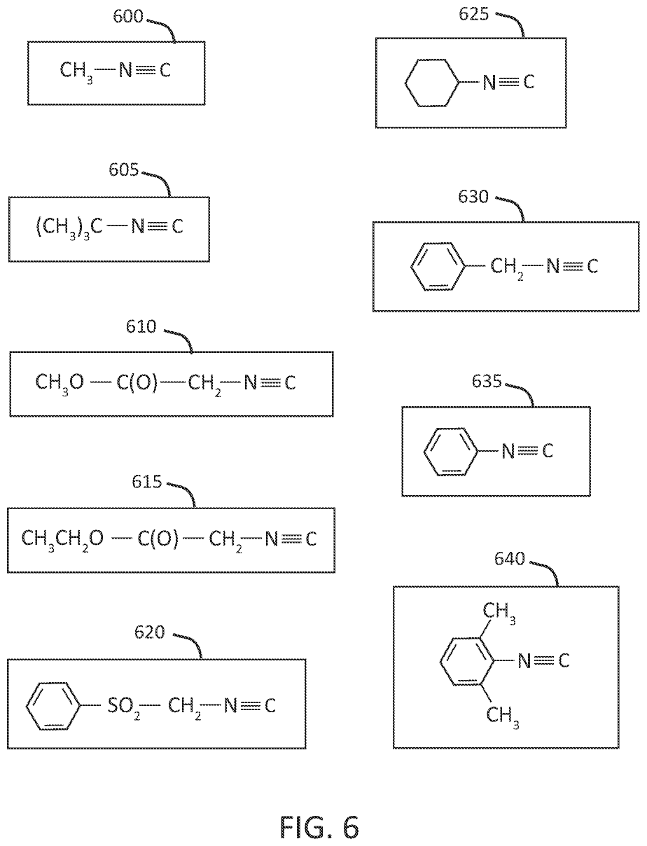

Partially manufactured semiconductor device 401 of FIG. 4A can be manufactured by exposing a surface of partially manufactured semiconductor device 400 to a reagent comprising isocyanide molecules. Some useful organic isocyanide molecules (R—NC, where R is an organic compound comprising carbon-carbon and carbon-hydrogen bonds, and optionally C—O, C—S, S—O, C—B, C—P, C—N, and/or C—Si bonds, and —NC is a functional group having a N—C triple bond) are, for example, provided in and described with respect to FIG. 6. A reagent comprising an isocyanide can be delivered to the surface of partially manufactured semiconductor device 400 in vapor form in a vacuum chamber under vacuum. The isocyanide can preferentially react with the exposed surface of metallic conductive region 421 forming isocyanide-containing layer 450. The isocyanide molecules react preferentially with metallic surfaces over metal nitrides, metal oxides, CHM, polymers primarily comprising carbon or nitrogen, or other materials or other dielectric materials. For example, if the surface of conductive region 421 is comprised of, for example, copper, tungsten, molybdenum, ruthenium, or an alloy thereof, the isocyanide can preferentially react with the surface of conductive region 421 through the formation of a chemical bond. The isocyanide-containing layer 450 can reversibly mask the conductive region 421 during one or more semiconductor manufacturing processes.

Partially manufactured semiconductor device 402 of FIG. 4B can be manufactured by depositing second dielectric regions 415 though a dielectric on dielectric deposition process employing, for example, a thermal atomic layer deposition (ALD) process. It is also possible to perform a metal-on-dielectric deposition (i.e., a deposition of a second different metal on the dielectric while masking the first metal). Second dielectric regions 415 comprise a material that can act as an etch stop in semiconductor manufacturing processes, such as, for example, SiO₂, SiN, SiC, SiCN, SiCO, Al₂O₃, TiO₂, TaN, AlN, ZrO₂, HfO₂, CN, BN, and/or CHM. The second dielectric regions 415 can comprise, for example, a dielectric material that may not function as an etch stop, such as a low-K dielectric, with a layer of etch stop material. Low-K dielectric materials can be the low-K dielectric materials described herein, although other materials are possible. Alternatively, second dielectric regions 415 can be comprised solely of a material that can function as an etch stop in semiconductor manufacturing processes. Isocyanide-containing layer 450 can be removed, for example, with a mildly acidic clean process, for example, 5% methanolic sulfuric acid, dilute HCL, or dilute or 50% HF. Removal of the isocyanide-containing layer 450 can result in the creation of residual process region 430. Residual process region 430 is comprised of a conductive material, such as for example, copper tungsten, molybdenum, and/or ruthenium, that also includes an amount of carbon and/or nitrogen that remains from a process used during the manufacture of the semiconductor device. Residual process region 430 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in a conductive material, such as a metal. Additionally, residual process region 430 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in copper. Additionally, the residual process region 430 can comprise 1 to 10% by weight of carbon and nitrogen and one or more additional parts of oxygen, sulfur, boron, phosphorous, and/or silicon. The composition of the residual process region 430 can depend, at least in part, on the organic isocyanide molecules (R—NC) selected.

Partially manufactured semiconductor device 403 can be manufactured by depositing third dielectric region 410, lithographically patterning the third dielectric region 410 to create trenches/vias, and depositing a conductive material 420 into the trenches/vias. The third dielectric region 415 can comprise, for example, a low-K dielectric, as described herein or another dielectric material. Conductive material 420 can be a metal, for example, copper, tungsten, molybdenum, ruthenium, or an alloy thereof.

FIGS. 4A-4B provide a further method of manufacturing a semiconductor device comprising trenches and/or vias. In FIG. 4A, partially manufactured semiconductor device 500 includes substrate 505, dielectric region 510, conductive region 521, and barrier layer 546. Substrate 505 can be a portion of a semiconductor device and can include layers containing semiconductor devices, such as transistors and memory cells. Dielectric region 510 can be comprised of a dielectric material such as, for example, SiO₂, SiCN, SiCO, or a low-K dielectric material. Low-K dielectrics include for example, fluorine-doped SiO₂, carbon-doped SiO₂, porous SiO₂, porous carbon-doped SiO₂, combinations for the foregoing, and also these materials with gas-filled gaps or bubbles. Dielectric region 510 can be an interlayer dielectric region.

Partially manufactured semiconductor device 501 includes isocyanide-containing layer 550. A conductive region 521 having an isocyanide-containing layer 550 can be manufactured using a process that exposes a surface of partially manufactured semiconductor device 500 to a reagent comprising isocyanide molecules. Some useful organic isocyanide molecules (R—NC, where R is an organic compound comprising carbon-carbon and carbon-hydrogen bonds) are, for example, provided in and described with respect to FIG. 6. A reagent comprising an isocyanide can be delivered to the surface of partially manufactured semiconductor device 500 in vapor form in a vacuum chamber under vacuum. The isocyanide can preferentially react with the exposed surface of metallic conductive region 521 forming isocyanide-containing layer 550. The isocyanide molecules react preferentially with metallic surfaces over metal nitrides, metal oxides, or dielectric materials. For example, if the surface of conductive region 521 is comprised of, for example, copper, tungsten, molybdenum, ruthenium, or an alloy thereof, the isocyanide can preferentially react with the surface of conductive region 521 through the formation of a chemical bond. The isocyanide-containing layer 550 can reversibly mask the conductive region 421 during one or more semiconductor manufacturing processes.

Partially manufactured semiconductor device 502 can be manufactured by depositing a barrier layer 545 on a surface of dielectric region 510. A barrier layer can be deposited, for example by an ALD process or chemical vapor deposition (CVD) process. Barrier layers 545 and 546 can be comprised of, for example, one or more layers of tantalum, tantalum nitride, cobalt, ruthenium, indium oxide, tungsten nitride, and/or titanium nitride. Other materials are possible. Removing the isocyanide-containing layer 550 advantageously leaves a surface of the conducting region without a barrier layer 545. Isocyanide-containing layer 550 can be removed, for example, with a mildly acidic clean process, for example, 5% methanolic sulfuric acid. Removal of the isocyanide-containing layer 550 can result in the creation of residual process region 530. Residual process region 530 is comprised of a conductive material, such as for example, copper tungsten, molybdenum, and/or ruthenium, that also includes an amount of carbon and/or nitrogen that remains from a process used during the manufacture of the semiconductor device. Residual process region 530 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in a conductive material, such as a metal. Additionally, residual process region 530 can comprise between 0.5 and 3% by weight of carbon and/or between 0.5 and 3% by weight of nitrogen, 1 to 2.5% by weight of carbon and/or 1 to 2.5% by weight of nitrogen, or 1 to 2% by weight of carbon and/or 1 to 2% by weight of nitrogen in copper. Partially manufactured semiconductor device 503 is created by depositing a conductive material to form conductive region 520. The conductive material can be a metal, such as, for example, copper.

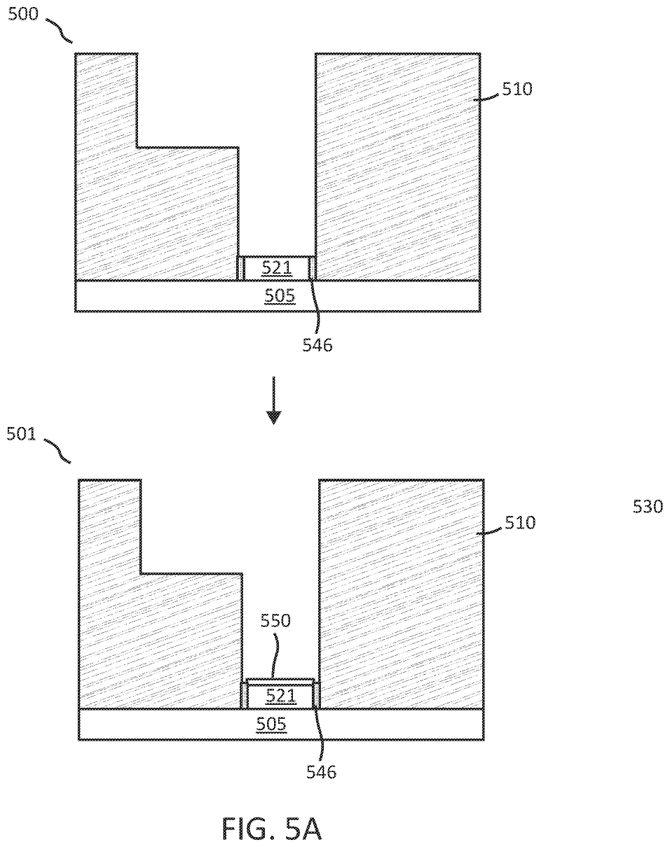

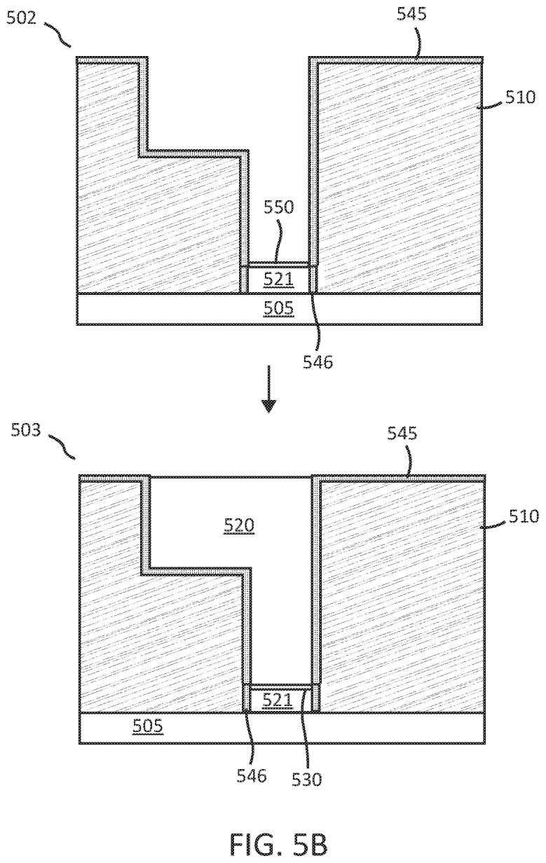

FIG. 6 shows some example isocyanide molecules that are useful, for example, as reagents in the methods described herein and with respect to FIGS. 4A-4B and 5A-5B. Useful isocyanides include organic isocyanides, such as for example, methyl isocyanide 600, tert-butyl isocyanide 605, methy isocyanoacetate 610, ethyl isocyanoacetate 615, toluenesulfonylmethyl isocyanide 620, cyclohexyl isocyanide 625, benzyl methylisocyanide 630, benzyl isocyanide 635, and 2,6-dimethylphenyl isocyanide 640. Additional R groups for R—NC, include, for example, N-isocyanoiminotriphenylphosphorane, adamantyl isocyanides, butyl isocyanide, 1,1,3,3-tetramethylburyl isocyanide, isopropyl isocyanide, 4-methoxyphenyl isocyanide, (trimethylsilyl)methyl isocyanide, and 2-morpholinoethyl isocyanide. Other isocyanides are also possible. The variety of R—NC molecules provides an ability to select a molecule that has advantageous properties for the process conditions and semiconductor device materials. In general, some substituted isocyanide molecules can be synthesized according to reaction (1).

RNHC(O)H+POCl₃→RNC+P(O)OHCl+2HCl (1)

In reaction (1), a formamide comprising the desired R group is reacted with phosphorous oxychloride to produce a desired RNC. Selection of an R group can tune the selectivity of ALD or CVD processes, the volatility of the RNC, and/or stability of the resulting isocyanide layer. Additionally, atoms that may leave unwanted impurities in resulting structures, such a phosphorous, sulfur, and silicon, can be avoided by selection of an R group that does not include these atoms.

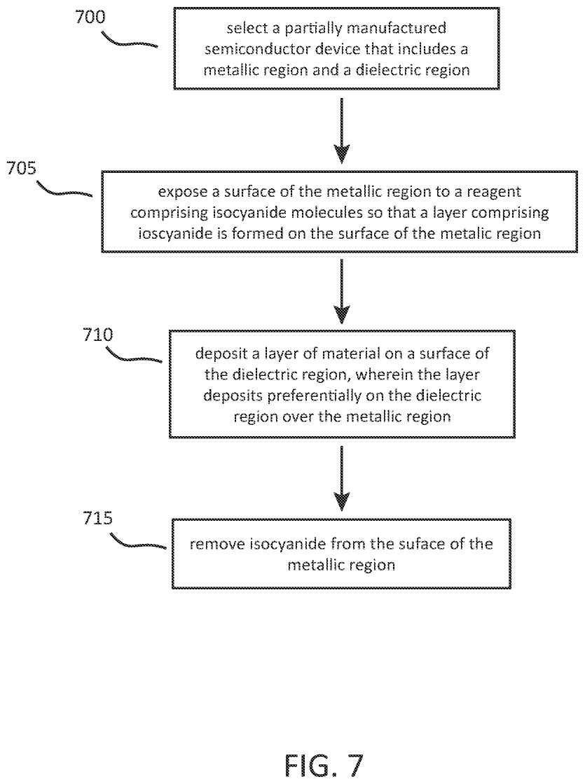

FIG. 7 describes a method for manufacturing a semiconductor device that employs an isocyanide layer. A partially manufactured semiconductor device that comprises a metallic region and a dielectric region is selected 700. The metallic region can be a conductive material, such as for example, copper tungsten, molybdenum, and/or ruthenium and the dielectric region can be a low-K dielectric such as one described herein. An exposed surface of the metallic region is reacted with a reagent comprising isocyanide molecules 705. The reagent comprising isocyanide molecules can be in the form of a vapor and the reaction can take place, for example, in a vacuum chamber. The isocyanide molecules include the molecules described herein, and for example, with respect to FIG. 6. The reaction creates a layer of material comprising isocyanide on the surface of the metallic region 705. A layer of material is deposited on the surface of the dielectric region 710. Because of the presence of the layer of material comprising isocyanide on the surface of the metallic region, the layer of material is deposited preferentially on the dielectric region rather than the metallic region 710. The isocyanide is removed from the surface of the metallic region 715. The isocyanide can be removed, for example, with a mildly acidic solution, such as for example, 5% methanolic sulfuric acid. The method of FIG. 7 can produce structures such as, for example, those of FIGS. 1, 2, and 3. Additionally, the illustrations and accompanying descriptions for FIGS. 4A-4B and 5A-5B provide additional details for the method described in FIG. 7.

Semiconductor device substrates (i.e., 105, 205, 405, 505) can be, for example, a silicon or silicon-on-insulator substate. Other materials for semiconductor substrates include, gallium arsenide, germanium, indium antimonide, lead telluride, indium phosphide, indium antimonide, indium gallium arsenide, or gallium antimonide. Other types of substrates are also possible and the devices described herein are not limited to a particular type of substrate.

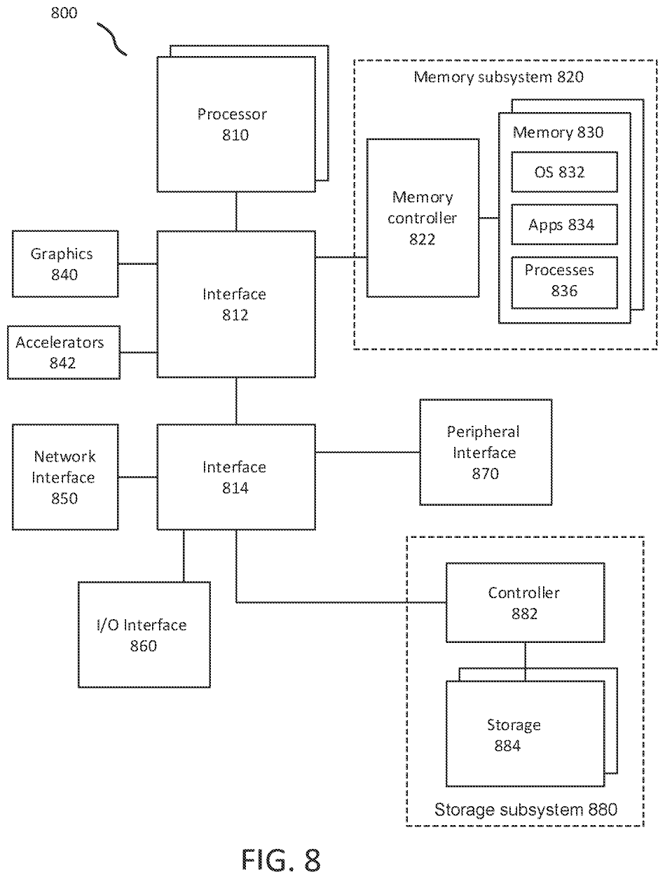

In FIGS. 1, 2, 3, 4A, 4B, 5A, 5B, and 7 the semiconductor devices (or chips) can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 8. The semiconductor chip packages described herein generally can be part of various larger package structures and configurations and the foregoing examples are not meant to limit the types of assemblies that are possible.

FIG. 8 depicts an example computing system. The computing system can be a system used for running equipment in a semiconductor fabrication plant. For example, instructions for performing methods associated with FIGS. 4A, 4B, 5A, 5B, and 7, can be stored and/or run on the computing system. A computing system 800 can include more, different, or fewer features than the ones described with respect to FIG. 8. Additionally, components of the computing system are semiconductor devices which can include the features described by FIGS. 1 and/or 2 and/or can have been manufactured according to the methods described herein and by FIGS. 4A, 4B, 5A, 5B, and 7.

Computing system 800 includes processor 810, which provides processing, operation management, and execution of instructions for system 800. Processor 810 can include any type of microprocessor, CPU (central processing unit), GPU (graphics processing unit), processing core, or other processing hardware to provide processing for system 800, or a combination of processors or processing cores. Processor 810 controls the overall operation of system 800, and can be or include, one or more programmable general-purpose or special-purpose microprocessors, DSPs, programmable controllers, ASICs, programmable logic devices (PLDs), or the like, or a combination of such devices.

In one example, computing system 800 includes interface 812 coupled to processor 810, which can represent a higher speed interface or a high throughput interface for system components needing higher bandwidth connections, such as memory subsystem 820 or graphics interface components 840, and/or accelerators 842. Interface 812 represents an interface circuit, which can be a standalone component or integrated onto a processor die. Where present, graphics interface 840 interfaces to graphics components for providing a visual display to a user of computing system 800. In one example, the display can include a touchscreen display.

Accelerators 842 can be a fixed function or programmable offload engine that can be accessed or used by a processor 810. For example, an accelerator among accelerators 842 can provide data compression (DC) capability, cryptography services such as public key encryption (PKE), cipher, hash/authentication capabilities, decryption, or other capabilities or services. In some cases, accelerators 842 can be integrated into a CPU socket (e.g., a connector to a motherboard (or circuit board, printed circuit board, mainboard, system board, or logic board) that includes a CPU and provides an electrical interface with the CPU). For example, accelerators 842 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 842 can provide multiple neural networks, CPUs, processor cores, general purpose graphics processing units, or graphics processing units can be made available for use by artificial intelligence (AI) or machine learning (ML) models.

Memory subsystem 820 represents the main memory of system 800 and provides storage for code to be executed by processor 810, or data values to be used in executing a routine. Memory subsystem 820 can include one or more memory devices 830 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 830 stores and hosts, among other things, operating system (OS) 832 that provides a software platform for execution of instructions in system 800, and stores and hosts applications 834 and processes 836. In one example, memory subsystem 820 includes memory controller 822, which is a memory controller to generate and issue commands to memory 830. The memory controller 822 can be a physical part of processor 810 or a physical part of interface 812. For example, memory controller 822 can be an integrated memory controller, integrated onto a circuit within processor 810.

System 800 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 800 includes interface 814, which can be coupled to interface 812. In one example, interface 814 represents an interface circuit, which can include standalone components and integrated circuitry. In one example, user interface components or peripheral components, or both, couple to interface 814. Network interface 850 provides computing system 800 the ability to communicate with remote devices (e.g., servers or other computing devices) over one or more networks. Network interface 850 can include an Ethernet adapter, wireless interconnection components, cellular network interconnection components, USB, or other wired or wireless standards-based or proprietary interfaces. Network interface 850 can transmit data to a device that is in the same data center or rack or a remote device, which can include sending data stored in memory.

Some examples of network interface 850 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 800 includes one or more input/output (I/O) interface(s) 860. I/O interface 860 can include one or more interface components through which a user interacts with system 800 (e.g., audio, alphanumeric, tactile/touch, or other interfacing). Peripheral interface 870 can include additional types of hardware interfaces, such as, for example, interfaces to semiconductor fabrication equipment and/or electrostatic charge management devices.

In one example, system 800 includes storage subsystem 880. Storage subsystem 880 includes storage device(s) 884, which can be or include any conventional medium for storing data in a nonvolatile manner, such as one or more magnetic, solid state, and/or optical based disks. Storage 884 can be generically considered to be a “memory,” although memory 830 is typically the executing or operating memory to provide instructions to processor 810. Whereas storage 884 is nonvolatile, memory 830 can include volatile memory (e.g., the value or state of the data is indeterminate if power is interrupted to system 800). In one example, storage subsystem 880 includes controller 882 to interface with storage 884. In one example controller 882 is a physical part of interface 812 or processor 810 or can include circuits or logic in both processor 810 and interface 814.

A power source (not depicted) provides power to the components of computing system 800. More specifically, power source typically interfaces to one or multiple power supplies in system 800 to provide power to the components of computing system 800.

Exemplary systems may be implemented in various types of computing, smart phones, tablets, personal computers, and networking equipment, such as switches, routers, racks, and blade servers such as those employed in a data center and/or server farm environment.

### EXAMPLES

A semiconductor device can comprise: a substrate, a first dielectric layer on the substrate, a conductive region in the first dielectric layer wherein the conductive region comprises a conductive layer that comprises between 0.5 and 3% by weight of carbon; and a second dielectric layer on the first dielectric layer wherein the second dielectric layer comprises a different material than the first dielectric layer. The conductive layer can also comprise between 0.5 and 3% by weight of nitrogen. The conductive layer can comprise between 1 and 2% by weight of carbon and between 1 and 2% by weight of nitrogen. The conductive region can comprise copper. The conductive region can comprise tungsten, molybdenum, cobalt, or ruthenium. The first dielectric layer can comprise a low-K dielectric and the second dielectric layer can comprise silicon dioxide, silicon nitride, silicon carbide, silicon carbonitride, aluminum oxide, or titanium dioxide.

An additional semiconductor device example can comprise: a substrate, a dielectric layer wherein the dielectric layer is on the substrate, a first conductive region in the dielectric layer wherein the first conductive region comprises a conductive layer that comprises between 0.5 and 3% by weight of carbon and between 0.5 and 3% by weight of nitrogen; a second conductive region wherein the second conductive region is on the first conductive region; and a barrier layer wherein the barrier layer is between the dielectric layer and the first conductive region and is not between the first conductive region and the second conductive region. The barrier layer can be comprised of one or more layers of tantalum, tantalum nitride, cobalt, ruthenium, indium oxide, tungsten nitride, or titanium nitride. The conductive layer can comprise between 1 and 2% by weight of carbon and between 1 and 2% by weight of nitrogen. The first and the second conductive regions can comprise copper. The dielectric layer can comprise a low-K dielectric. The first conductive region can comprise copper and a layer of tungsten, cobalt, molybdenum, or ruthenium.

A method for manufacturing a semiconductor device can comprise: selecting a partially manufactured semiconductor device wherein the partially manufactured semiconductor device comprises a metallic region and a dielectric region; exposing a surface of the metallic region to a reagent comprising isocyanide molecules wherein a layer comprising isocyanide is formed on the surface of the metallic region; depositing a layer of material on a surface of the dielectric region wherein the layer of material deposits preferentially on the surface of the dielectric region over the surface of the metallic region; and removing isocyanide from the surface of the metallic region. The layer of material on the surface of the dielectric region can be a dielectric material. The layer of material on the surface of the dielectric region can be comprised of a low-K dielectric material. The layer of material on the surface of the dielectric region can be comprised of silicon dioxide, silicon nitride, silicon carbide, silicon carbonitride, aluminum oxide, titanium dioxide. The layer of material on the surface of the dielectric region can be comprised of fluorine-doped SiO₂, carbon-doped SiO₂, porous SiO₂, porous carbon-doped SiO₂. The layer of material on the surface of the dielectric region can be comprised of a barrier layer. The layer of material on the surface of the dielectric region can be comprised of one or more layers of tantalum, tantalum nitride, cobalt, ruthenium, indium oxide, tungsten nitride, or titanium nitride. The metallic region can be comprised of copper, tungsten, molybdenum, ruthenium, cobalt, or an alloy thereof.

Besides what is described herein, various modifications can be made to what is disclosed. Therefore, the illustrations and examples herein should be construed in an illustrative, and not a restrictive sense.

What is claimed is:

1. A semiconductor device comprising:
a substrate,
a first dielectric layer on the substrate,
a conductive region in the first dielectric layer wherein the conductive region comprises a conductive layer that comprises between 0.5 and 3% by weight of carbon; and
a second dielectric layer on the first dielectric layer wherein the second dielectric layer comprises a different material than the first dielectric layer.

2. The semiconductor device of claim 1, wherein the conductive layer also comprises between 0.5 and 3% by weight of nitrogen.

3. The semiconductor device of claim 1 wherein the conductive layer comprises between 1 and 2% by weight of carbon and between 1 and 2% by weight of nitrogen.

4. The semiconductor device of claim 1 wherein the conductive region comprises copper.

5. The semiconductor device of claim 1 wherein the conductive region comprises tungsten, molybdenum, cobalt, or ruthenium.

6. The semiconductor device of claim 1 wherein the first dielectric layer comprises a low-K dielectric and the second dielectric layer comprises silicon dioxide, silicon nitride, silicon carbide, silicon carbonitride, aluminum oxide, or titanium dioxide.

7. A semiconductor device comprising:
a substrate,
a dielectric layer wherein the dielectric layer is on the substrate,
a first conductive region in the dielectric layer wherein the first conductive region comprises a conductive layer that comprises between 0.5 and 3% by weight of carbon and between 0.5 and 3% by weight of nitrogen;
a second conductive region wherein the second conductive region is on the first conductive region; and
a barrier layer wherein the barrier layer is between the dielectric layer and the first conductive region and is not between the first conductive region and the second conductive region.

8. The semiconductor device of claim 7, wherein the barrier layer is comprised of one or more layers of tantalum, tantalum nitride, cobalt, ruthenium, indium oxide, tungsten nitride, or titanium nitride.

9. The semiconductor device of claim 7, wherein the conductive layer comprises between 1 and 2% by weight of carbon and between 1 and 2% by weight of nitrogen.

10. The semiconductor device of claim 7 wherein the first and the second conductive regions comprise copper.

11. The semiconductor device of claim 7, wherein the dielectric layer comprises a low-K dielectric.

12. The semiconductor device of claim 7, wherein the first conductive region comprises copper and a layer of tungsten, cobalt, molybdenum, or ruthenium.

13. A method for manufacturing a semiconductor device comprising:
selecting a partially manufactured semiconductor device wherein the partially manufactured semiconductor device comprises a metallic region and a dielectric region;
exposing a surface of the metallic region to a reagent comprising isocyanide molecules wherein a layer comprising isocyanide is formed on the surface of the metallic region;
depositing a layer of material on a surface of the dielectric region wherein the layer of material deposits preferentially on the surface of the dielectric region over the surface of the metallic region; and
removing isocyanide from the surface of the metallic region.

14. The method of claim 13, wherein the layer of material on the surface of the dielectric region is a dielectric material.

15. The method of claim 13, wherein the layer of material on the surface of the dielectric region is comprised of a low-K dielectric material.

16. The method of claim 13, wherein the layer of material on the surface of the dielectric region is comprised of silicon dioxide, silicon nitride, silicon carbide, silicon carbonitride, aluminum oxide, titanium dioxide.

17. The method of claim 13, wherein the layer of material on the surface of the dielectric region is comprised of fluorine-doped SiO₂, carbon-doped SiO₂, porous SiO₂, porous carbon-doped SiO₂.

18. The method of claim 13, wherein the layer of material on the surface of the dielectric region is comprised of a barrier layer.

19. The method of claim 13, wherein the layer of material on the surface of the dielectric region is comprised of one or more layers of tantalum, tantalum nitride, cobalt, ruthenium, indium oxide, tungsten nitride, or titanium nitride.

20. The method of claim 13 wherein the metallic region is comprised of copper, tungsten, molybdenum, ruthenium, cobalt, or an alloy thereof.
